(19) United States
(12) Patent Application Publication
(10) Pub. No.: US 2020/0146192 A1
(43) Pub. Date: May 7, 2020

(54) SEMICONDUCTOR ASSEMBLY HAVING DUAL WIRING STRUCTURES AND WARP BALANCER

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 16/727,661

(22) Filed: Dec. 26, 2019

Related U.S. Application Data
(63) Continuation-in-part of application No. 16/279,696, filed on Feb. 19, 2019.
Application No. 16/279,696 is a continuation-in-part of application No. 16/411,949, filed on May 14, 2019.
Application No. 16/279,696 is a continuation-in-part of application No. 16/046,243, filed on Jul. 26, 2018, now abandoned.
Application No. 16/046,243 is a continuation-in-part of application No. 14/846,987, filed on Sep. 7, 2015, now Pat. No. 10,420,204.
Application No. 14/846,987 is a continuation-in-part of application No. 15/605,920, filed on May 25, 2017, now abandoned.
Application No. 15/605,920 is a continuation-in-part of application No. 15/642,253, filed on Jul. 5, 2017.
Application No. 15/642,253 is a continuation-in-part of application No. 15/785,426, filed on Oct. 16, 2017.
Application No. 15/785,426 is a continuation-in-part of application No. 15/881,119, filed on Jan. 26, 2018.
Application No. 15/881,119 is a continuation-in-part of application No. 15/908,838, filed on Mar. 1, 2018, now abandoned.
Application No. 15/908,838 is a continuation-in-part of application No. 15/976,307, filed on May 10, 2018, now abandoned.
Application No. 16/411,949 is a continuation-in-part of application No. 16/400,879, filed on May 1, 2019, now abandoned.
Application No. 16/046,243 is a continuation-in-part of application No. 14/846,987, filed on Sep. 7, 2015, now Pat. No. 10,420,204.
Application No. 14/846,987 is a continuation-in-part of application No. 15/080,427, filed on Mar. 24, 2016, now abandoned.
Application No. 15/080,427 is a continuation-in-part of application No. 15/605,920, filed on May 25, 2017, now abandoned.
Application No. 15/605,920 is a continuation-in-part of application No. 15/642,253, filed on Jul. 5, 2017.
Application No. 15/642,253 is a continuation-in-part of application No. 15/881,119, filed on Jan. 26, 2018.
Application No. 15/881,119 is a continuation-in-part of application No. 15/908,838, filed on Mar. 1, 2018, now abandoned.
Application No. 15/908,838 is a continuation-in-part of application No. 15/976,307, filed on May 10, 2018, now abandoned.
Application No. 14/846,987 is a continuation-in-part of application No. 14/621,332, filed on Feb. 12, 2015, now abandoned.
Application No. 15/080,427 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/642,253 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/785,426 is a continuation-in-part of application No. 15/642,253, filed on Jul. 5, 2017.
Application No. 15/642,253 is a continuation-in-part of application No. 15/642,256, filed on Jul. 5, 2017, now abandoned.
Application No. 15/881,119 is a continuation-in-part of application No. 15/605,920, filed on May 25, 2017, now abandoned.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/908,838 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/473,629, filed on Mar. 30, 2017, now Pat. No. 10,134,711.
Application No. 15/473,629 is a continuation-in-part of application No. 15/642,253, filed on Jul. 5, 2017.
Application No. 15/415,844 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 15/415,846 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 15/473,629 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 15/353,537 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/462,536, filed on Mar. 17, 2017, now abandoned.
Application No. 15/289,126 is a continuation-in-part of application No. 15/166,185, filed on May 26, 2016, now Pat. No. 10,121,768.
Application No. 15/353,537 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/462,536 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 16/400,879 is a continuation-in-part of application No. 15/605,920, filed on May 25, 2017, now abandoned.
Application No. 15/605,920 is a continuation-in-part of application No. 15/881,119, filed on Jan. 26, 2018.
(60) Provisional application No. 61/949,652, filed on Mar. 7, 2014.
(60) Provisional application No. 62/166,771, filed on May 27, 2015.

(51) Int. Cl. H05K 13/00; H05K 13/04; H05K 1/02; H01L 23/498; H01L 21/56; H01L 21/48

(52) U.S. Cl. CPC H05K 13/00; H05K 13/0486; H05K 13/0469; H05K 1/0204; H01L 23/49838; H01L 21/568; H01L 23/3121; H01L 21/4857; H05K 2203/063; H05K 2203/025; H05K 2201/0187; H01L 2224/16227; H01L 2224/18; H01L 23/49822

(57) ABSTRACT

The semiconductor assembly includes a semiconductor chip, a first wiring structure and a second wiring structure. The second wiring structure includes a warp balancer, a core layer, a top build-up layer and a bottom build-up layer. The warp balancer is laterally surrounded by the core layer and preferably has an elastic modulus higher than 100 GPa. The top and the bottom build-up layers are electrically connected to each other through the warp balancer or the core layer therebetween. The first wiring structure is disposed over the top build-up layer through connecting joints superimposed over the warp balancer. By the high modulus of the warp balancer, local thermo-mechanical stress can be counterbalanced to suppress warping and bending of the first and second wiring structures. Furthermore, mounting the first wiring structure over the second wiring structure can provide staged fan-out routing for the chip to improve routing efficiency and production yield.

### CROSS REFERENCE TO RELATED APPLICATIONS

This application is a continuation-in-part of U.S. application Ser. No. 16/279,696 filed Feb. 19, 2019 and a continuation-in-part of U.S. application Ser. No. 16/411,949 filed May 14, 2019. The U.S. application Ser. No. 16/279,696 is a continuation-in-part of U.S. application Ser. No. 16/046,243 filed Jul. 26, 2018, a continuation-in-part of U.S. application Ser. No. 14/846,987 filed Sep. 7, 2015, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/785,426 filed Oct. 16, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018. The U.S. application Ser. No. 16/411,949 is a continuation-in-part of U.S. application Ser. No. 16/400,879 filed May 1, 2019.

The U.S. application Ser. No. 16/046,243 is a continuation-in-part of U.S. application Ser. No. 14/846,987 filed Sep. 7, 2015, a continuation-in-part of U.S. application Ser. No. 15/080,427 filed Mar. 24, 2016, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018. The U.S. application Ser. No. 14/846,987 is a continuation-in-part of U.S. application Ser. No. 14/621,332 filed Feb. 12, 2015. The U.S. application Ser. No. 15/080,427 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/642,253 is a continuation-in-part of U.S. application Ser. No. 14/621,332 filed Feb. 12, 2015, and a continuation-in-part of U.S. application Ser. No. 14/846,987 filed Sep. 7, 2015. The U.S. application Ser. No. 15/785,426 is a continuation-in-part of U.S. application Ser. No. 15/642,253 filed Jul. 5, 2017 and a continuation-in-part of U.S. application Ser. No. 15/642,256 filed Jul. 5, 2017. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/908,838 is a continuation-in-part of U.S. application Ser. No. 15/415,844 filed Jan. 25, 2017, a continuation-in-part of U.S. application Ser. No. 15/415,846 filed Jan. 25, 2017, a continuation-in-part of U.S. application Ser. No. 15/473,629 filed Mar. 30, 2017 and a continuation-in-part of U.S. application Ser. No. 15/642,253 filed Jul. 5, 2017. The U.S. application Ser. No. 15/976,307 is a division of pending U.S. patent application Ser. No. 14/621,332 filed Feb. 12, 2015.

The U.S. application Ser. No. 14/621,332 claims benefit of U.S. Provisional Application Ser. No. 61/949,652 filed Mar. 7, 2014. The U.S. application Ser. Nos. 15/415,844 and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, a continuation-in-part ofUS application Ser. No. 15/289,126 filed Oct. 8, 2016, a continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. No. 15/462,536 is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The U.S. application Ser. No. 16/400,879 is a continuation-in-part of U.S. application Ser. No. 15/605,920 filed May 25, 2017 and a continuation-in-part of U.S. application Ser. No. 15/881,119 filed Jan. 26, 2018. The entirety of each of said applications is incorporated herein by reference.

### FIELD OF THE INVENTION

The present invention relates to a semiconductor assembly and, more particularly, to a semiconductor assembly having dual wiring structures and a warp balancer.

### DESCRIPTION OF RELATED ART

High performance microprocessors and ASICs require advanced packaging technologies such as flip chip assembly to address various performance needs. However, the routing density of the conventional laminate substrates is generally low, and therefore does not have adequate interconnection capability for chips with high I/O density. Coreless substrates that are built by semi-additive process can meet the demands. However, other features such as mechanical integrity and reliability are not addressed (ref U.S. Pat. Nos. 8,227,703 and 8,860,205). This is because that flip chip assembly tends to warp after chip attachment on substrate (as shown in FIG. 1). This coefficient of thermal expansion (CTE) mismatch induced warpage may result in disconnection between the semiconductor chip 15 and the circuit layer 13 on the resin layer 11, making flip chip assemblies unreliable especially for very large die or ultra-small bump assembly (ref U.S. Pat. Nos. 9,185,799 and 10,068,812).

In view of the various development stages and limitations in current substrates, an urgent need exists to develop an interconnect system that can meet the ultra-high routing density requirements and also achieve high level assembly reliability.

### SUMMARY OF THE INVENTION

The objective of the present invention is to provide a semiconductor assembly in which a semiconductor chip is connected to a first wiring structure through a plurality of bumps. The first wiring structure has a high routing density and serves as the first-level interconnects for the semiconductor chip, thereby allowing signal continuity and integrity. The first wiring structure is then connected to a second wiring structure with a warp balancer embedded therein. As the warp balancer is a material with high elastic modulus, local thermo-mechanical stress induced by CTE mismatch during thermal cycling can be counterbalanced to suppress warping and bending of the first wiring structure and the flip-chip assembly, thereby ensuring production yield and assembly reliability.

In accordance with the foregoing and other objectives, the present invention provides a semiconductor assembly, comprising: a semiconductor chip; a first wiring structure including at least one dielectric layer and at least one conductive layer formed in an alternate fashion, wherein the semiconductor chip is electrically connected to the first wiring structure through a plurality of bumps; and a second wiring structure, including a warp balancer having a top surface, a bottom surface and a peripheral sidewall, a core layer having a top surface and a bottom surface and laterally surrounding the peripheral sidewall of the warp balancer, a top build-up layer that is disposed over the top surfaces of the warp balancer and the core layer, and a bottom build-up layer that is disposed under the bottom surfaces of the warp balancer and the core layer and is electrically connected to the top build-up layer through at least one of the warp balancer and the core layer. The first wiring structure is electrically connected to the second wiring structure through a plurality of connecting joints, wherein the connecting joints are superimposed over the warp balancer, and the bumps are superimposed over the first wiring structure.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a conventional flip-chip assembly;

FIG. 2 is a cross-sectional view of a first wiring structure formed on a sacrificial carrier in accordance with the first embodiment of the present invention;

FIG. 3 is a cross-sectional view of a warp balancer in accordance with the first embodiment of the present invention;

FIG. 4 is a cross-sectional view of the structure of FIG. 3 further provided with a core layer in accordance with the first embodiment of the present invention;

FIG. 5 is a cross-sectional view of the structure of FIG. 4 further provided with a top build-up layer and a bottom build-up layer to finish the fabrication of a second wiring structure in accordance with the first embodiment of the present invention;

FIG. 6 is a cross-sectional view of the structure of FIG. 2 connected to the second wiring structure of FIG. 5 in accordance with the first embodiment of the present invention;

FIG. 7 is a cross-sectional view of the structure of FIG. 6 further provided with an underfill in accordance with the first embodiment of the present invention;

FIG. 8 is a cross-sectional view of the structure of FIG. 7 after removal of the sacrificial carrier to finish the fabrication of an interconnect substrate in accordance with the first embodiment of the present invention;

FIG. 9 is a cross-sectional view of a semiconductor assembly having semiconductor chips electrically connected to the interconnect substrate of FIG. 8 in accordance with the first embodiment of the present invention;

FIG. 10 is a cross-sectional view of another aspect of the interconnect substrate in accordance with the first embodiment of the present invention;

FIG. 11 is a cross-sectional view of a semiconductor assembly having a semiconductor chip electrically connected to the interconnect substrate of FIG. 10 in accordance with the first embodiment of the present invention;

FIG. 12 is a cross-sectional view of a second wiring structure in accordance with the second embodiment of the present invention;

FIG. 13 is a cross-sectional view of an interconnect substrate having a first wiring structure connected to the second wiring structure of FIG. 12 in accordance with the second embodiment of the present invention;

FIG. 14 is a cross-sectional view of a semiconductor assembly having a semiconductor chip electrically connected to the interconnect substrate of FIG. 13 and an additional first wiring structure in accordance with the second embodiment of the present invention;

FIG. 15 is a cross-sectional view of another aspect of the second wiring structure in accordance with the second embodiment of the present invention;

FIG. 16 is a cross-sectional view of a semiconductor assembly having semiconductor chips electrically connected to the second wiring structure of FIG. 15 through a first wiring structure in accordance with the second embodiment of the present invention;

FIG. 17 is a cross-sectional view of a semiconductor assembly in accordance with the third embodiment of the present invention;

FIG. 18 is a cross-sectional view of another aspect of the semiconductor assembly in accordance with the third embodiment of the present invention;

FIG. 19 is a cross-sectional view of a semiconductor assembly in accordance with the fourth embodiment of the present invention; and

FIG. 20 is a cross-sectional view of another aspect of the semiconductor assembly in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

FIGS. 2-9 are cross-sectional views showing a method of making a semiconductor assembly that includes a first wiring structure, a second wiring structure, and semiconductor chips in accordance with the first embodiment of the present invention.

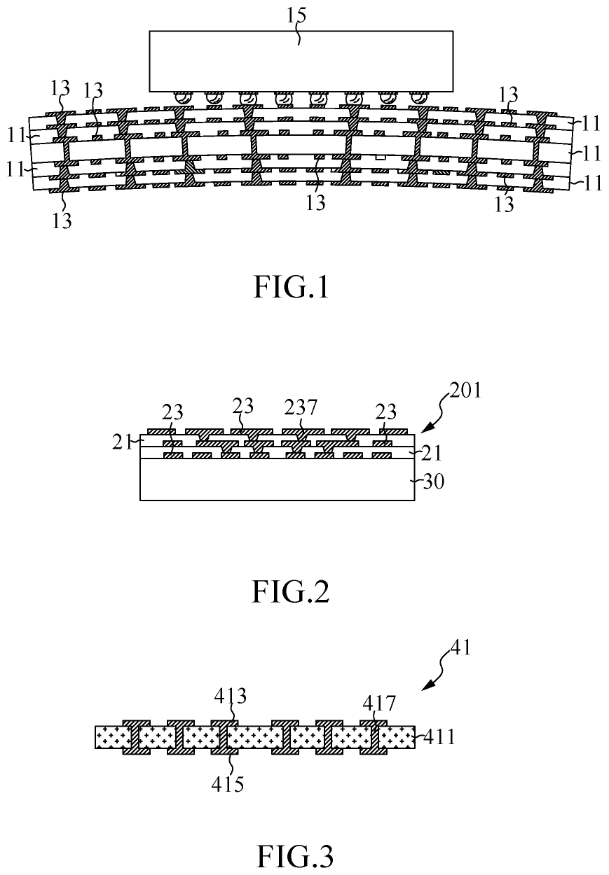

FIG. 1 is a cross-sectional view of the structure with a first wiring structure 201 detachably adhered to a sacrificial carrier 30. The first wiring structure 201 can be directly formed on the sacrificial carrier 30 through buildup process. The sacrificial carrier 30 can be made of any peelable or removable material, such as silicon, copper, aluminum, iron, nickel, tin or alloys thereof. In this embodiment, the first wiring structure 201 is illustrated as a multi-layered build-up circuitry and includes multiple dielectric layers 21 and multiple conductive layers 23 serially formed in an alternate fashion. The innermost one of the conductive layers 23 extend laterally on the sacrificial carrier 30, and the others extend laterally on their corresponding dielectric layers 21 and include metallized vias 27 in the dielectric layers 21.

FIG. 3 is a cross-sectional view of a warp balancer 41 having top contact pads 413 and bottom contact pads 415 at its top and bottom surfaces, respectively. For required stiffness, the warp balancer 41 typically includes a high-modulus plate 411, which can be made of an inorganic material and preferably has an elastic modulus higher than 100 Gpa and a thickness of 0.2 mm or more. The top contact pads 413 are disposed on the top surface of the high-modulus plate 411, whereas the bottom contact pads 415 are disposed on the bottom surface of the high-modulus plate 411. Additionally, the warp balancer 41 further includes metallized through vias 417 penetrating through the high-modulus plate 411. As a result, the top contact pads 413 and the bottom contact pads 415 can be electrically connected to each other through the metallized through vias 417.

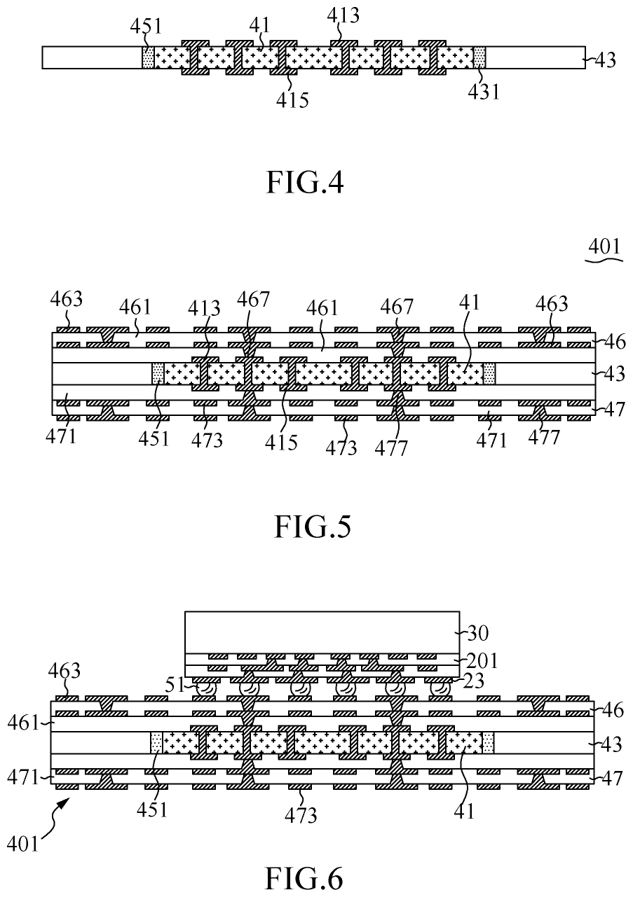

FIG. 4 is a cross-sectional view of the structure with the warp balancer 41 attached in a through opening 431 of a core layer 43 using a resin adhesive 451. The warp balancer 41 is spaced from and adhered to the inner sidewall of the through opening 431 of the core layer 43 using the resin adhesive 451 in a gap between the peripheral sidewall of the warp balancer 41 and the inner sidewall of the through opening 431. The material of the core layer 43 is not particularly limited and may be any organic or inorganic material. For instance, the core layer 43 may be made of a resin-based material and typically have an elastic modulus lower than 20 GPa and is highly temperature dependent.

FIG. 5 is a cross-sectional view of the structure provided with a top build-up layer 46 and a bottom build-up layer 47 on two opposite sides of the warp balancer 41 and the core layer 43. The top build-up layer 46 is disposed over the top surfaces of the warp balancer 41 and the core layer 43 as well as the resin adhesive 451. The bottom build-up layer 47 is disposed under the bottom surfaces of the warp balancer 41 and the core layer 43 as well as the resin adhesive 451. In this embodiment, the top build-up layer 46 and the bottom build-up layer 47 are illustrated as multi-layered structures and electrically connected to each other through the warp balancer 41. The top build-up layer 46 includes multiple binding resins 461 and multiple conductive traces 463 serially formed in an alternate fashion. Likewise, the bottom build-up layer 47 includes multiple binding resins 471 and multiple conductive traces 473 serially formed in an alternate fashion. Each conductive trace 463, 473 extends laterally on its corresponding binding resin 461, 471 and includes metallized vias 467, 477 in the binding resin 461, 471. As a result, the conductive traces 463 of the top build-up layer 46 can be electrically coupled to each other through the metallized vias 467, and the innermost conductive trace 463 of the top build-up layer 46 is electrically coupled to the top contact pads 413 of the warp balancer 41 through the metallized vias 467. Likewise, the conductive traces 473 of the bottom build-up layer 47 are electrically coupled to each other through the metallized vias 477, and the innermost conductive trace 473 of the bottom build-up layer 47 is electrically coupled to the bottom contact pads 415 of the warp balancer 41 through the metallized vias 477.

At this stage, a second wiring structure 401 is accomplished and includes the warp balancer 41, the core layer 43, the resin adhesive 451, the top build-up layer 46 and the bottom build-up layer 47. By the high modulus of the warp balancer 41, the local thermo-mechanical stress induced by thermal cycling can be counterbalanced to ensure global flatness of the second wiring structure 401. In this embodiment, the warp balancer 41 has an elastic modulus higher than 100 GPa, which is greater than those of the core layer 43, the top build-up layer 46 and the bottom build-up layer 47.

FIG. 6 is a cross-sectional view of the structure with the first wiring structure 201 of FIG. 2 mounted over the second wiring structure 401 of FIG. 5. The first wiring structure 201 typically has a smaller surface than that of the second wiring structure 401 and is electrically connected to the second wiring structure 401 through a plurality of connecting joints 51. In this embodiment, the connecting joints 51 are illustrated as solder balls and superimposed over the warp balancer 41 of the second wiring structure 401. As the connecting joints 51 are mounted at the area covered by the warp balancer 41, the connection reliability between the first wiring structure 201 and the second wiring structure 401 can be ensured.

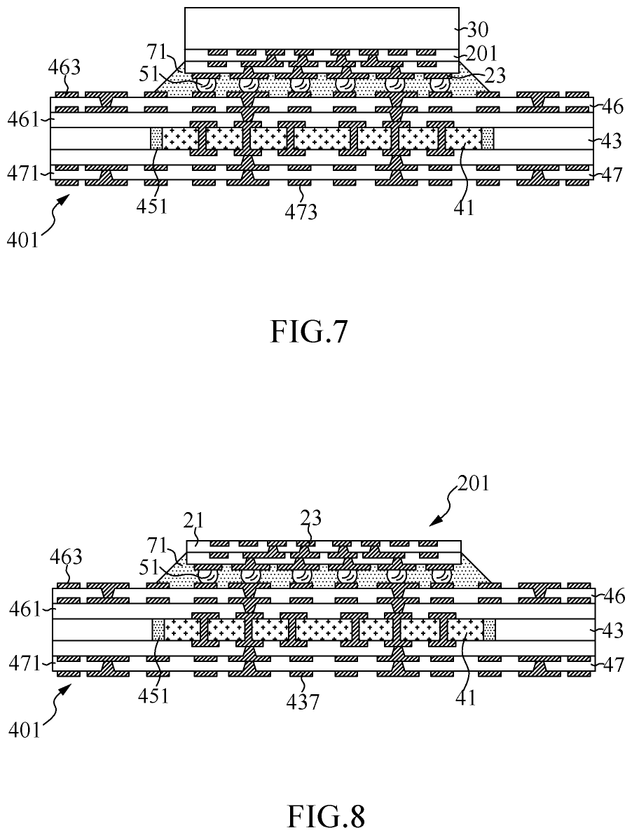

FIG. 7 is a cross-sectional view of the structure with an underfill 71 dispensed between the first wiring structure 201 and the second wiring structure 401. The underfill 71 fills the gap between the first wiring structure 201 and the top build-up layer 46 of the second wiring structure 401. As a result, the underfill 71 can act as encapsulant of the connecting joints 51 as well as a binder between the first wiring structure 201 and the second wiring structure 401.

FIG. 8 is a cross-sectional view of the structure after removal of the sacrificial carrier 30. By removing the sacrificial carrier 30, the first wiring structure 201 is exposed from the above to provide electrical contacts for subsequent chip connection. As a result, an interconnect substrate is accomplished and includes the first wiring structure 201 and the second wiring structure 401. The first wiring structure 201 typically has an elastic modulus lower than that of the warp balancer 41. As the first wiring structure 201 is superimposed over the high-modulus warp balancer 41 and mechanically locked to the second wiring structure 401 by the underfill 71, the flatness of the first wiring structure 201 separated from the sacrificial carrier 30 can be maintained during thermal cycling.

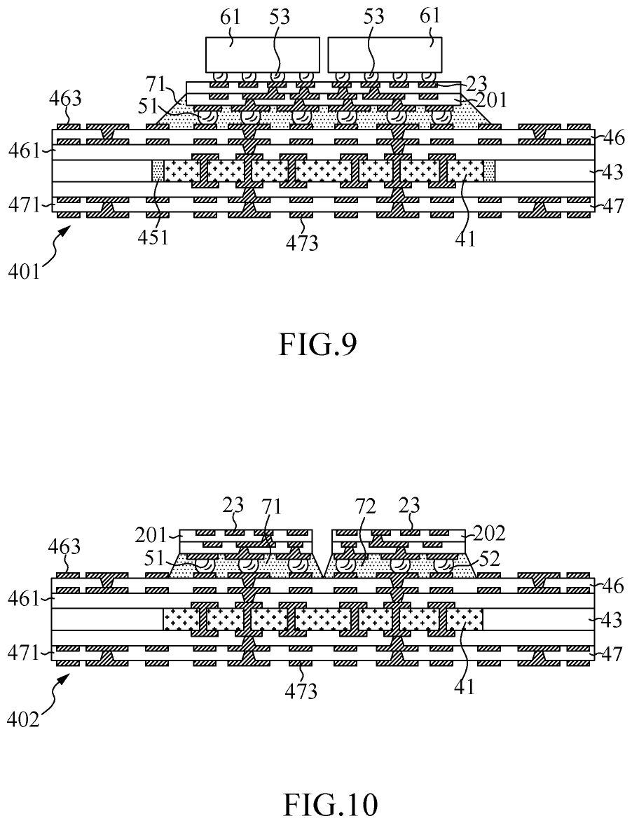

FIG. 9 is a cross-sectional view of a semiconductor assembly with semiconductor chips 61 electrically connected to interconnect substrate of FIG. 8. The semiconductor chips 61 are face-down mounted over the top surface of the first wiring structure 201 through bumps 53 superimposed over the first wiring structure 201 and the warp balancer 41. In this illustration, the size of the bumps 53 disposed between the semiconductor chips 61 and the first wiring structure 201 is smaller than that of the connecting joints 51 disposed between the first wiring structure 201 and the second wiring structure 401. As a result, the first wiring structure 201 can provide first level fan-out routing for the semiconductor chips 61, and the second wiring structure 401 provides further fan-out routing for the first wiring structure 201. Due to the high elastic modulus of the warp balancer 41, the bending or deformation of the first wiring structure 201 and the second wiring structure 401 can be effectively suppressed to avoid electrical connection failure between the semiconductor chips 61 and the first wiring structure 201 and between the first wiring structure 201 and the second wiring structure 401.

FIG. 10 is a cross-sectional view of another aspect of the interconnect substrate in accordance with the first embodiment of the present invention. The second wiring structure 402 for this aspect is similar to that illustrated in FIG. 8, except that the core layer 43 laterally surrounds and conformally coats and directly contacts the peripheral sidewall of the warp balancer 41 without any resin adhesive between the warp balancer 41 and the core layer 43. In this illustration, there are a plurality of first wiring structures 201, 202 electrically connected to the top build-up layer 46 of the second wiring structure 402 through connecting joints 51, 52 superimposed over the warp balancer 41. Further, underfills 71, 72 are dispensed between the first wiring structures 201, 202 and the second wiring structure 402.

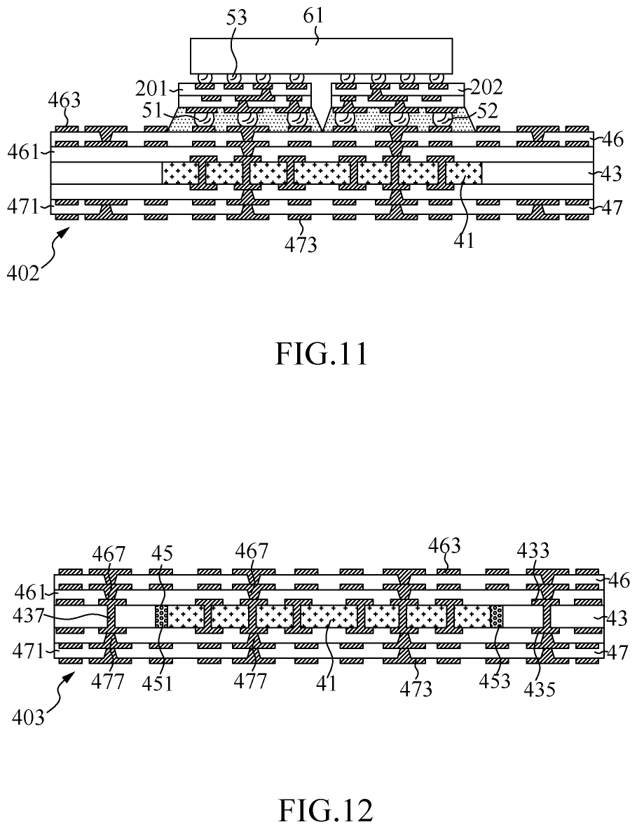

FIG. 11 is a cross-sectional view of a semiconductor assembly with a semiconductor chip 61 electrically connected to interconnect substrate of FIG. 10. The semiconductor chip 61 is superimposed over the warp balancer 41 and flip-chip connected to the first wiring structures 201, 202 through bumps 53. As a result, the semiconductor chip 61 can be electrically connected to the second wiring structure 402 through the first wiring structures 201, 202.

### Embodiment 2

FIGS. 12-14 are cross-sectional views showing a method of making a semiconductor assembly in accordance with the second embodiment of the present invention.

For purposes of brevity, any description in Embodiment 1 is incorporated herein insofar as the same is applicable, and the same description need not be repeated.

FIG. 12 is a cross-sectional view of a second wiring structure 403 which is similar to that illustrated in FIG. 5, except that the core layer 43 has vertical connecting elements 437, and a plurality of modulators 453 are dispensed in the resin adhesive 451 to form a modified binding matrix 45 in the gap between the peripheral sidewall of the warp balancer 41 and the inner sidewall of the core layer 43. The CTE of the modulators 453 typically is lower than that of the resin adhesive 451 so as to effectively reduce the risk of resin cracking. For significant effect, the CTE of the modulators 453 preferably is lower by at least 10 ppm/° C. than that of the resin adhesive 451. In this embodiment, the modified binding matrix 45 contains the modulators 453 in an amount of at least 30% by volume based on the total volume of the gap, and preferably has a coefficient of thermal expansion of lower than 50 ppm/° C. As a result, the internal expansion and shrinkage of the modified binding matrix 45 during thermal cycling can be alleviated so as to restrain its cracking. Additionally, for effectively releasing thermo-mechanical induced stress, the modified binding matrix 45 preferably has a sufficient width of more than 10 micrometers (more preferably 25 micrometers or more) in the gap to absorb the stress. The vertical connecting elements 437 provide electrical connection pathways between the top and bottom surfaces of the core layer 43 and are electrically coupled to the top build-up layer 46 and the bottom build-up layer 47 through additional metallized vias 467, 477 in contact with the top patterned metal 433 and the bottom patterned metal 435 of the core layer 43.

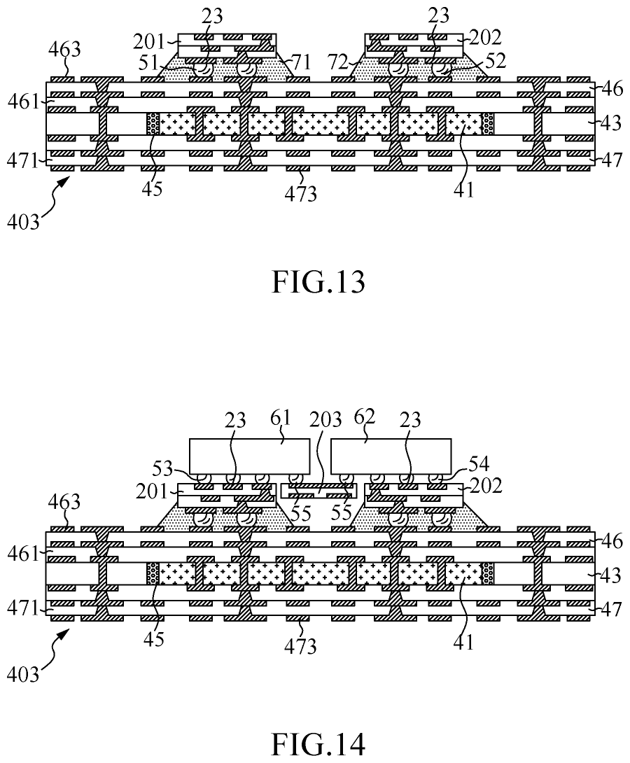

FIG. 13 is a cross-sectional view of an interconnect substrate having first wiring structures 201, 202 electrically connected to the second wiring structure 403 of FIG. 12. The first wiring structures 201, 202 are mounted over the top build-up layer 46 of the second wiring structure 403 through connecting joints 51, 52 and underfills 71, 72. The connecting joints 51, 52 are superimposed over the warp balancer 41 and contact the conductive trace 463 at the top surface of the second wiring structure 403 and the conductive layer 23 at the bottom surface of the first wiring structures 201, 202. The underfills 71, 72 mechanically lock the bottom surface of the first wiring structures 201, 202 to the top surface of the second wiring structure 402.

FIG. 14 is a cross-sectional view of a semiconductor assembly with semiconductor chips 61, 62 electrically connected to the interconnect substrate of FIG. 13 and an additional first wiring structure 203. The semiconductor chips 61, 62 are flip-chip connected to the first wiring structures 201, 202 through bumps 53, 54 respectively, and to the additional first wiring structure 203 through additional bumps 55. As a result, the semiconductor chips 61, 62 can be electrically connected to the second wiring structure 403 through the first wiring structures 201, 202 and to each other through the additional first wiring structure 203.

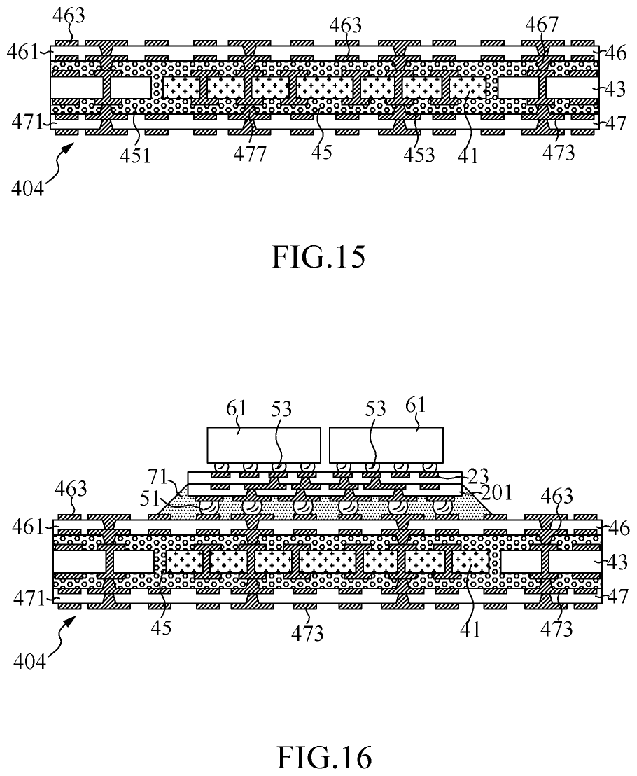

FIG. 15 is a cross-sectional view of another aspect of the second wiring structure in accordance with the second embodiment of the present invention. The second wiring structure 404 is similar to that illustrated in FIG. 12, except that the modified binding matrix 45 further extends outside of the gap and further covers the top and bottom surfaces of the warp balancer 41 and the top and bottom surfaces of the core layer 43. Based on the total volume of the modified binding matrix 45, the amount of the modulators 453 contained in the modified binding matrix 45 preferably is at least 30% by volume. In this illustration, the innermost conductive traces 463, 473 of the top build-up layer 46 and the bottom build-up layer 47 laterally extend on the top and bottom surfaces of the modified binding matrix 45, respectively, and include metallized vias 467, 477 in the modified binding matrix 45 for electrical connection with the warp balancer 41 and the core layer 43.

FIG. 16 is a cross-sectional view of a semiconductor assembly having a first wiring structure 201 and semiconductor chips 61 stacked on the second wiring structure 404 of FIG. 15. The first wiring structure 201 is superimposed over the warp balancer 41 and attached to the top surface of the second wiring structure 404 through connecting joints 51 and an underfill 71. As a result, an interconnect substrate is accomplished and electrically connected to the semiconductor chips 61 through bumps 53 between the first wiring structure 201 and the semiconductor chips 61.

### Embodiment 3

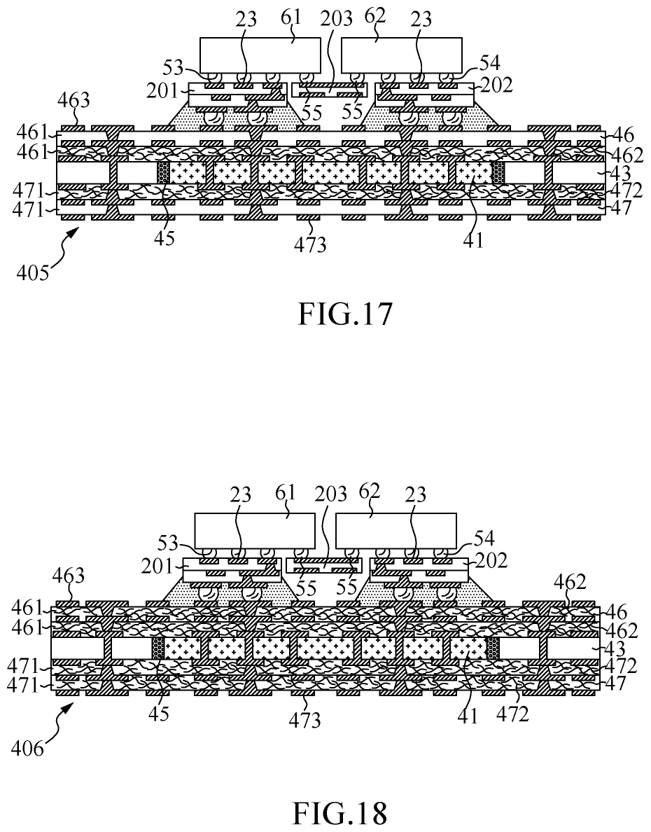

FIG. 17 is a cross-sectional view of a semiconductor assembly in accordance with the third embodiment of the present invention.

For purposes of brevity, any description in the Embodiments above is incorporated herein insofar as the same is applicable, and the same description need not be repeated.

The semiconductor assembly of this embodiment is similar to that illustrated in FIG. 14, except that the top build-up layer 46 of the second wiring structure 405 further includes a top continuous interlocking fiber sheet 462 impregnated in the innermost top binding resin 461, and the bottom build-up layer 47 of the second wiring structure 405 further includes a bottom continuous interlocking fiber sheet 472 impregnated in the innermost bottom binding resin 471. The continuous interlocking fibers can be carbon fibers, silicon carbide fibers, glass fibers, nylon fibers, polyester fibers or polyamide fibers. More specifically, the top continuous interlocking fiber sheet 462 and the bottom continuous interlocking fiber sheet 472 covers the interfaces between the warp balancer 41 and the modified binding matrix 45 and between the core layer 43 and the modified binding matrix 45 from above and below, respectively. By virtue of the fiber interlocking configuration, the top continuous interlocking fiber sheet 462 and the bottom continuous interlocking fiber sheet 472 can prevent detachment induced by cracks formed within the modified binding matrix 45, and also serve as a crack stopper to restrain undesirable cracks from extending to the conductive traces 463, 473. In this illustration, the top continuous interlocking fiber sheet 462 further laterally extends over and covers the top surfaces of the warp balancer 41, the core layer 43 and the modified binding matrix 45, whereas the bottom continuous interlocking fiber sheet 472 further laterally extends under and covers the bottom surfaces of the warp balancer 41, the core layer 43 and the modified binding matrix 45. As a result, the reliability of the conductive traces 463, 473 spaced from the modified binding matrix 45 by the top continuous interlocking fiber sheet 462 and the bottom continuous interlocking fiber sheet 472 can be ensured.

FIG. 18 is a cross-sectional view of another aspect of the semiconductor assembly in accordance with the third embodiment of the present invention. The semiconductor assembly of this aspect is similar to that illustrated in FIG. 18, except that the top build-up layer 46 of the second wiring structure 406 further includes an additional top continuous interlocking fiber sheet 462 impregnated in the outermost top binding resin 461, and the bottom build-up layer 47 of the second wiring structure 406 further includes an additional bottom continuous interlocking fiber sheet 472 impregnated in the outermost bottom binding resin 471.

### Embodiment 4

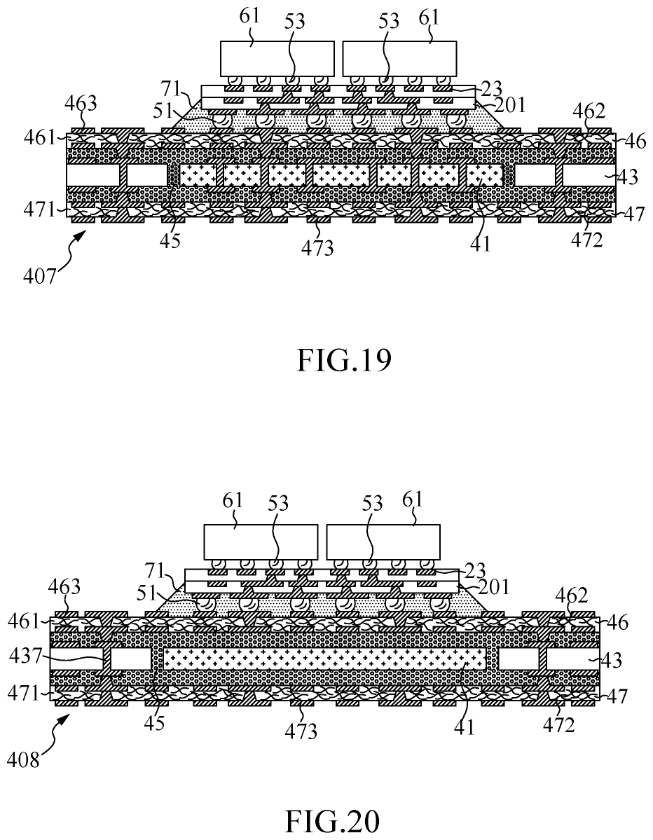

FIG. 19 is a cross-sectional view of a semiconductor assembly in accordance with the fourth embodiment of the present invention.

For purposes of brevity, any description in the Embodiments above is incorporated herein insofar as the same is applicable, and the same description need not be repeated.

The semiconductor assembly of this embodiment is similar to that illustrated in FIG. 16, except that the top build-up layer 46 of the second wiring structure 407 further includes a top continuous interlocking fiber sheet 462 impregnated in the top binding resin 461, and the bottom build-up layer 47 of the second wiring structure 407 further includes a bottom continuous interlocking fiber sheet 472 impregnated in the bottom binding resin 471. The top continuous interlocking fiber sheet 462 covers the modified binding matrix 45 and the innermost conductive trace 463 from above. The bottom continuous interlocking fiber sheet 472 covers the modified binding matrix 45 and the innermost conductive trace 473 from below.

FIG. 20 is a cross-sectional view of another aspect of the semiconductor assembly in accordance with the fourth embodiment of the present invention. The semiconductor assembly of this aspect is similar to that illustrated in FIG. 19, except that no top and bottom contact pads and metallized through vias are provided in the warp balancer 41. As a result, in the second wiring structure 408 of this aspect, the top build-up layer 46 and the bottom build-up layer 47 are electrically connected to each other through the core layer 43.

As illustrated in the aforementioned embodiments, a distinctive semiconductor assembly is configured to exhibit improved reliability, in which a semiconductor chip is bump-connected to an interconnect substrate having a higher-modulus warp balancer under a solder joint region. The interconnect substrate includes a first wiring structure and a second wiring structure located under the first wiring structure. The first wiring structure and the second wiring structure provide staged fan-out routing for chip connection. In a preferred embodiment, the second wiring structure mainly includes a warp balancer, a core layer, a top build-up layer and a bottom build-up layer, and the first wiring structure has a smaller surface area than that of the second wiring structure and is superimposed over the warp balancer of the second wiring structure.

The warp balancer is a non-electronic component and typically has an elastic modulus higher than that of the core layer, the top and bottom build-up layers and the first wiring structure. Preferably, the elastic modulus of the warp balancer is higher than 100 GPa so that the warp balancer can have sufficient rigidity to maintain the global flatness of the interconnect substrate and the semiconductor assembly using the same. Optionally, the warp balancer may include top contact pads at its top surface for electrical connection with the top build-up layer and bottom contact pads at its bottom surface for electrical connection with the bottom build-up layer. The top contact pads and the bottom contact pads can be electrically connected to each other through metallized through vias.

The core layer may be made of a resin-based material typically having an elastic modulus lower than 20 GPa, and can directly contact the peripheral sidewall of the warp balancer or have an inner sidewall spaced from the peripheral sidewall of the warp balancer. In a preferred embodiment, the core layer has a through opening, and the warp balancer disposed in the through opening of core layer can be adhered to the inner sidewall of the through opening using a resin adhesive. Typically, the CTE of the resin adhesive may be extremely higher than those of the warp balancer and the core layer, and thus is prone to crack induced by internal expansion and shrinkage during thermal cycling in a confined area. In order to reduce the risk of adhesive cracking, a plurality of modulators, having lower CTE than that of the resin adhesive, may be further dispensed in the resin adhesive to form a modified binding matrix in the gap between the peripheral sidewall of the warp balancer and the inner sidewall of the through opening. Preferably, the modulators are in an amount of at least 30% (preferably 50% or more) by volume based on the total volume of the gap, and the difference in CTE between the resin adhesive and the modulators is 10 ppm/° C. or more so as to exhibit significant effect. As a result, the modified binding matrix can have CTE lower than 50 ppm/° C., and the internal expansion and shrinkage of the modified binding matrix during thermal cycling can be alleviated so as to restrain its cracking. Furthermore, for effectively releasing thermo-mechanical induced stress, the modified binding matrix preferably has a sufficient width of more than 10 micrometers (more preferably 25 micrometers or more) in the gap to absorb the stress. Further, the modified binding matrix may extend outside of the gap and further cover the top surface and/or the bottom surface of the warp balancer and the core layer. By the lateral extension of the modified binding matrix over/under the warp balancer and the core layer, the interfacial stress between the modified binding matrix and the warp balancer and between the modified binding matrix and the core layer can be dispersed so as to conduce to further reduction of cracking risk. Optionally, the core layer may include at least one first vertical connecting element electrically coupled to the top build-up layer and the bottom build-up layer. As a result, the core layer can provide signal vertical transduction pathways or/and power delivery and return pathways between the top build-up layer and the bottom build-up layer.

The top and bottom build-up layers are disposed at two opposite sides of the warp balancer and the core layer, and each typically includes at least one binding resin and at least one conductive trace that includes metallized vias in the binding resin and extends laterally on the binding resin. The binding resin and the conductive trace are serially formed in an alternate fashion and can be in repetition if needed for further signal routing. As a result, the top and bottom build-up layers can be electrically connected to the top and bottom contact pads of the warp balancer and/or the vertical connecting element of the core layer through the metallized vias. In consideration of the strict flatness requirement for the second wiring structure, the thickness of the top build-up layer preferably is substantially equal to or close to that of the bottom build-up layer. Optionally, the top build-up layer may include a top continuous interlocking fiber sheet that covers the top surface of the modified binding matrix, whereas the bottom build-up layer may include a bottom continuous interlocking fiber sheet that covers the bottom surface of the modified binding matrix. The top continuous interlocking fiber sheet can be impregnated in at least one binding resin of the top build-up layer and cover the top ends of the interfaces between the modified binding matrix and the warp balancer and between the modified binding matrix and the core layer. Likewise, the bottom continuous interlocking fiber sheet can be impregnated in at least one binding resin of the bottom build-up layer and cover the bottom ends of the interfaces between the modified binding matrix and the warp balancer and between the modified binding matrix and the core layer. More specifically, the top continuous interlocking fiber sheet can laterally extend above and cover the top surfaces of the warp balancer, the core layer and the modified binding matrix, whereas the bottom continuous interlocking fiber sheet can laterally extend below and cover the bottom surfaces of the warp balancer, the core layer and the modified binding matrix. By interlocking configuration of the top and bottom continuous interlocking fiber sheets, the risk of cracking in the modified binding matrix can be further reduced. Even if cracks are generated at interfaces or/and formed in the modified binding matrix, the interlocking fiber sheets can also serve as a crack stopper to restrain the cracks from extending into the top and bottom build-up layers so as to ensure reliability of the conductive traces of the top and bottom build-up layers.

The first wiring structure can be first formed on a sacrificial carrier and then electrically connected to the top build-up layer through connecting joints. By the sacrificial carrier, the flatness of the first wiring structure can be maintained when soldering the first wiring structure to the second wiring structure. Preferably, the first wiring structure is superimposed over the warp balancer, and all the connecting joints are entirely positioned within the area completely covered by the warp balancer and do not laterally extend beyond peripheral edges of the warp balancer. Before removal of the sacrificial carrier, an underfill preferably is dispensed in a gap between the bottom surface of the first wiring structure and the top surface of the second wiring structure. As a result, the flatness of the first wiring structure separated from the sacrificial carrier can be maintained during thermal cycling. The first wiring structure may be a multi-layered build-up circuitry without a core layer and typically has a smaller surface area than those of the top build-up layer and the bottom build-up layer. More specifically, the first wiring structure can include at least one dielectric layer and at least one conductive layer that includes metallized vias in the dielectric layer and extends laterally on the dielectric layer. The dielectric layer and the conductive layer are serially formed in an alternate fashion and can be in repetition if needed for further signal routing. Accordingly, the first wiring structure includes electrical contacts at its exposed top surface for subsequent chip connection.

The semiconductor chip is mounted over the top surface of the first wiring structure through bumps (such as gold or solder bumps). As a result, the semiconductor chip can be electrically connected to the second wiring structure through the first wiring structure. Preferably, the bumps are superimposed over the warp balancer of the second wiring structure. The semiconductor chip can be a packaged or unpackaged chip. Furthermore, the semiconductor chip can be a bare chip, or a wafer level packaged die, etc.

The term “cover” refers to incomplete or complete coverage in a vertical and/or lateral direction For instance, in a preferred embodiment, the warp balancer completely covers the connecting joints regardless of whether another element such as the top build-up layer between warp balancer and the connecting joints. Likewise, in a preferred embodiment, the warp balancer also completely covers the bumps regardless of whether other elements such as the top build-up layer and the first wiring structure between warp balancer and the bumps.

The term “surround” refers to relative position between elements regardless of whether another element is between the elements. For instance, in a preferred embodiment, the core layer laterally surrounds the warp balancer regardless of whether another element (such as the resin adhesive) is between the warp balancer and the core layer.

The phrases “mounted over”, “attached to”, “extend over”, “disposed over/on/under” and “superimposed over” include contact and non-contact between elements. For instance, in a preferred embodiment, the semiconductor chip is mounted on the first wiring structure regardless of whether the semiconductor chip is separated from the first wiring structure by the bumps.

The interconnect substrate and the semiconductor assembly made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A semiconductor assembly, comprising:
a semiconductor chip;
a first wiring structure including at least one dielectric layer and at least one conductive layer formed in an alternate fashion, wherein the semiconductor chip is electrically connected to the first wiring structure through a plurality of bumps; and
a second wiring structure, including:
a warp balancer having a top surface, a bottom surface and a peripheral sidewall;
a core layer having a top surface and a bottom surface and laterally surrounding the peripheral sidewall of the warp balancer;
a top build-up layer that is disposed over the top surfaces of the warp balancer and the core layer; and
a bottom build-up layer that is disposed under the bottom surfaces of the warp balancer and the core layer and is electrically connected to the top build-up layer through at least one of the warp balancer and the core layer;
wherein the first wiring structure is electrically connected to the second wiring structure through a plurality of connecting joints, and the connecting joints are superimposed over the warp balancer.

2. The semiconductor assembly of claim 1, wherein an elastic modulus of the warp balancer is higher than that of the core layer.

3. The semiconductor assembly of claim 1, wherein an elastic modulus of the warp balancer is higher than 100 GPa.

4. The semiconductor assembly of claim 1, wherein an elastic modulus of the first wiring structure is lower than that of the warp balancer.

5. The semiconductor assembly of claim 1, wherein the first wiring structure has a smaller surface area than that of the second wiring structure.

6. The semiconductor assembly of claim 1, wherein the size of the bumps disposed between the semiconductor chip and the first wiring structure is smaller than that of the connecting joints disposed between the first wiring structure and the second wiring structure.

7. The semiconductor assembly of claim 1, further comprising an underfill dispensed between the first wiring structure and the second wiring structure.

8. The semiconductor assembly of claim 1, wherein (i) the warp balancer includes top contact pads at the top surface thereof and bottom contact pads at the bottom surface thereof, (ii) the top contact pads are electrically connected to the bottom contact pads, (iii) the top build-up layer is electrically coupled to the top contact pads, and (iv) the bottom build-up layer is electrically coupled to the bottom contact pads.

9. The semiconductor assembly of claim 1, further comprising an additional first wiring structure electrically connected to the second wiring structure through additional connecting joints, wherein the additional connecting joints are superimposed over the warp balancer, and the semiconductor chip is further electrically connected to the additional first wiring structure through additional bumps.

10. The semiconductor assembly of claim 1, wherein the core layer has a through opening, and the warp balancer is disposed in the through opening of the core layer.

11. The semiconductor assembly of claim 10, wherein the warp balancer is adhered to an inner sidewall of the through opening through a resin adhesive.

12. The semiconductor assembly of claim 11, further comprising a plurality of modulators dispensed in the resin adhesive to form a modified binding matrix in a gap between the peripheral sidewall of the warp balancer and the inner sidewall of the through opening, wherein the coefficient of thermal expansion of the modulators is lower than that of the resin adhesive.

13. The semiconductor assembly of claim 12, wherein the coefficient of thermal expansion of the modified binding matrix is lower than 50 ppm/V.

14. The semiconductor assembly of claim 13, wherein the modified binding matrix having a width of more than 10 micrometers in the gap.

15. The semiconductor assembly of claim 12, wherein the top build-up layer includes a top continuous interlocking fiber sheet that covers a top surface of the modified binding matrix in the gap between the warp balancer and the core layer.

16. The semiconductor assembly of claim 12, wherein the bottom build-up layer includes a bottom continuous interlocking fiber sheet that covers a bottom surface of the modified binding matrix in the gap between the warp balancer and the core layer.
